(19) United States
(12) Patent Application Publication
(10) Pub. No.: US 2025/0148376 A1
(43) Pub. Date: May 8, 2025

(54) POWER FEATURE AIDED MACHINE LEARNING TO REDUCE NON-LINEAR DISTORTION

(71) Applicant: Telefonaktiebolaget LM Ericsson (publ), Stockholm (SE)

(72) Inventors: Hao GAO, Beijing (CN); Sener DIKMESE, Sundbyberg (SE); Ang FENG, Solna (SE); Marcus ERIKSSON, Järfälla (SE); Mats Gan KLINGBERG, Enebyberg (SE)

(21) Appl. No.: 18/837,025

(22) PCT Filed: Feb. 25, 2022
(86) PCT No.: PCT/CN2022/077972

§ 371 Date: Aug. 8, 2024

(51) Int. Cl. G06N 20/20; H03F 1/32; H03F 3/24

(52) U.S. Cl. CPC G06N 20/20; H03F 1/3241; H03F 3/245

(57) ABSTRACT

A computer-implemented method performed by a device configured with a power feature aided machine learning, ML, model is provided that models a behavior of a DPD to reduce non-linear distortion of an output signal of a non-linear device. The method includes extracting a plurality of power features from an input signal destined to be input to the DPD. The method further includes labelling the extracted plurality of power features to obtain at least one labelled average power level; inputting the at least one labelled average power level to the input of the ML model to obtain an output signal from the ML model having characteristics to reduce the non-linear distortion of the output signal of the non-linear device; and providing the output signal from the ML model as an input to the non-linear device.

### TECHNICAL FIELD

The present disclosure relates generally to a device configured with a power feature aided machine learning, ML, model that models a behavior of a digital predistortion, DPD, to reduce non-linear distortion of an output signal of a non-linear device, and related methods and apparatuses.

### BACKGROUND

Wireless communication devices (e.g., base stations and/or user equipments (UEs)) such as fourth generation (4G) long term evolution (LTE), fifth generation (5G), and 5G-beyond based devices use nonconstant-envelope in-phase/quadrature (I/Q) modulated signals, such as orthogonal frequency division multiplexing (OFDM) and filtered OFDM. Signals with such a device, e.g. a power amplifier (PA), naturally may excite non-linearities of some components in the device (such as in a component in a radio unit of a base station or in a component of a UE). Some approaches, e.g. focusing on the transmitter side, may try to compensate for this non-linear behavior with PA and digital predistortion (DPD) modeling.

### SUMMARY

There currently exist certain challenges. Evolution of emerging radio frequency (RF) systems may present features with new challenges for non-linear device and/or DPD behavior modeling. For example, complex non-linear device architectures (such as multiband and multimode PAs), may significantly improve energy efficiency of the system, but may be difficult to model to obtain desired linear gain. However, with new waveforms such as new radio (NR) in 5G including wider signal bandwidth, it may be important to model non-linear device and/or DPD accurately over a wider frequency range. As a consequence, non-linear device and/or DPD behavior modeling may need to consider much more complicated non-linearities and memory effects.

Additionally, in today's wireless communication systems such as 4G LTE-A and 5G, transmission power may vary with real-time traffic over time (referred to herein as “dynamic traffic effects”). Thus, dynamic changes appearing on the non-linear device input may impact (e.g., significantly impact) non-linear behavior of a non-linear device. Existing approaches for non-linear device and/or DPD behavior modeling, however, may work in scenarios where the non-linear devices are operated at mostly static conditions, but may not work in scenarios where the non-linear device is operated during dynamic traffic effects. Accurate non-linear device and/or DPD behavior modeling under dynamic traffic may be important and may not be ignorable in realistic transmission scenarios.

Further, “trapping effects” appearing in semiconductor materials in a non-linear device may introduce long-term memory effects that may span in the range of, e.g., milliseconds. The physical origin of trapping effects may be associated with active device surface and buffer traps. While present manufacturing processes may have reduced surface traps, buffer traps may still be present. Additionally, long-term memory effects also may be a result of “electron-thermal effects” caused by dynamic temperature variations due to self-heating. As a consequence, non-linear device and/or DPD behavior modeling may need to be able to handle the long-term memory effects to have sufficient accuracy on the behaviors of the non-linear device and/or DPD.

Existing approaches for non-linear device and/or DPD behavior modeling, e.g. using memory polynomial (MP) and generalized memory polynomial (GMP), may lack ability to address these and other challenges.

Certain aspects of the disclosure and their embodiments may provide solutions to these or other challenges.

In various embodiments, a computer-implemented method performed by a device configured with a power feature aided ML model is provided that models a behavior of a DPD to reduce non-linear distortion of an output signal of a non-linear device. The method includes extracting, for a point in time in a time period, a plurality of power features from an input signal destined to be input to the DPD. The method further includes labelling the extracted plurality of power features to obtain at least one labelled average power level. The method further includes inputting the at least one labelled average power level to the input of the ML model to obtain an output signal from the ML model having characteristics to reduce the non-linear distortion of the output signal of the non-linear device. The method further includes providing the output signal from the ML model as an input to the non-linear device.

In some embodiments, the ML model comprises a tree-based power feature aided gradient boosting, GB, model and/or power feature aided extreme gradient boosting, XGB, model.

In some embodiments, the method further includes training of the power feature aided GB model and/or the power feature aided XGB model to learn the behavior of the digital predistortion, DPD, for the non-linear device.

In some embodiments, the method further includes applying the power feature aided GB model and/or the power feature aided XGB model online to perform the providing. The method further includes periodically updating the power feature aided GB model and/or the power feature aided XGB model with the power feature aided GB model based training and/or the power feature aided XGB model based training to learn behavior of the DPD for the non-linear device.

In some embodiments, the method further includes modeling a behavior of the non-linear device.

In other embodiments, a device configured with a power feature aided ML model is provided that models a behavior of a DPD to reduce non-linear distortion of an output signal of a non-linear device. The device includes at least one processor; and at least one memory connected to the at least one processor and storing program code that is executed by the at least one processor to perform operations. The operations include extracting, for a point in time in a time period, a plurality of power features from an input signal destined to be an input to the DPD. The operations further include labelling the extracted plurality of power features to obtain at least one labelled average power level. The operations further include inputting the at least one labelled average power level to the input of the ML model to obtain an output signal from the ML model having characteristics to reduce the non-linear distortion of the output signal of the non-linear device. The operations further include providing the output signal from the ML model as an input to the non-linear device.

In some embodiments, a device configured with a power feature aided ML model is provided that models a behavior of a DPD to reduce non-linear distortion of an output signal of a non-linear device. The device is adapted to perform operations. The operations include extracting, for a point in time in a time period, a plurality of power features from an input signal destined to be an input to the DPD. The operations further include labelling the extracted plurality of power features to obtain at least one labelled average power level. The operations further include inputting the at least one labelled average power level to the input of the ML model to obtain an output signal from the ML model having characteristics to reduce the non-linear distortion of the output signal of the non-linear device. The operations further include providing the output signal from the ML model as an input to the non-linear device.

In some embodiments, a computer program comprising program code to be executed by processing circuitry of a device configured with a power feature aided ML model is provided that models a behavior of a DPD to reduce non-linear distortion of an output signal of a non-linear device, whereby execution of the program code causes the device to perform operations. The operations include extracting, for a point in time in a time period, a plurality of power features from an input signal destined to be an input to the DPD. The operations further include labelling the extracted plurality of power features to obtain at least one labelled average power level. The operations further include inputting the at least one labelled average power level to the input of the ML model to obtain an output signal from the ML model having characteristics to reduce the non-linear distortion of the output signal of the non-linear device. The operations further include providing the output signal from the ML model as an input to the non-linear device.

In some embodiments, a computer program product comprising a non-transitory storage medium including program code to be executed by processing circuitry of a device configured with a power feature aided ML model is provided that models a behavior of a DPD to reduce non-linear distortion of an output signal of a non-linear device, whereby execution of the program code causes the device to perform operations. The operations include extracting. for a point in time in a time period, a plurality of power features from an input signal destined to be an input to the DPD. The operations further include labelling the extracted plurality of power features to obtain at least one labelled average power level. The operations further include inputting the at least one labelled average power level to the input of the ML model to obtain an output signal from the ML model having characteristics to reduce the non-linear distortion of the output signal of the non-linear device. The operations further include providing the output signal from the ML model as an input to the non-linear device.

### BRIEF DESCRIPTION OF DRAWINGS

The accompanying drawings, which are included to provide a further understanding of the disclosure and are incorporated in and constitute a part of this application, illustrate certain non-limiting embodiments of inventive concepts. In the drawings:

FIG. 1 is a block diagram illustrating a DPD process using (i) a GMP/MP approach, and (ii) GB and XGB based model with online implementation;

FIG. 2 is a schematic illustrating GB regression in terms of algorithm iterations as an ensemble of decision trees, DTs, in accordance with some embodiments of the present disclosure;

FIG. 3 is a flowchart illustrating operations of a device in accordance with some embodiments of the present disclosure;

FIG. 4 is a block diagram illustrating power feature assisted ML prediction for DPD behavior modeling in accordance with some embodiments;

FIGS. 5 and 6 are flowcharts illustrating operations of a device in accordance with some embodiments of the present disclosure;

FIG. 7 is a block diagram illustrating an example embodiment of an offline implementation of PA and DPD behavior modeling (training) in accordance with some embodiments of the present disclosure;

FIG. 8 is a block diagram illustrating an example embodiment of an online implementation of PA and DPD behavior modeling (predicting) in accordance with some embodiments of the present disclosure;

FIG. 9 is a block diagram illustrating an example embodiment of an online implementations of power feature assisted ML based training and prediction in accordance with some embodiments of the present disclosure;

FIG. 10 is a schematic diagram illustrating an electron trapping circuit model in which the charge is controlled by a drain voltage;

FIG. 11 is a schematic diagram illustrating an electron-thermal circuit model of a transistor from the junction of a non-linear device to a sink of the non-linear device;

FIG. 12 is a schematic diagram illustrating a matching (biasing) circuit model for a PA;

FIG. 13 is a plot illustrating variation of power levels due to dynamic traffic in accordance with some embodiments of the present disclosure;

FIG. 14 is a plot illustrating normalized power spectral densities (PSDs) of ideal input signal, actual PA output signal, and predicted PA output signals for a PA operating at 46.8 dBm output power under a 60 MHz new radio (NR) signal;

FIG. 15 is a plot illustrating normalized PSDs of ideal input signal, actual PA output signal, and predicted PA output signals for a PA operating five different output powers under a 60 MHz new radio (NR) signal in accordance with some embodiments of the present disclosure;

FIG. 16 is a block diagram of a communication system in accordance with some embodiments of the present disclosure;

FIG. 17 is a block diagram of a user equipment in accordance with some embodiments of the present disclosure;

FIG. 18 is a block diagram of a network node in accordance with some embodiments of the present disclosure; and

FIG. 19 is a block diagram of a virtualization environment in accordance with some embodiments of the present disclosure,

### DETAILED DESCRIPTION

Inventive concepts will now be described more fully hereinafter with reference to the accompanying drawings, in which examples of embodiments of inventive concepts are shown. Inventive concepts may, however, be embodied in many different forms and should not be construed as limited to the embodiments set forth herein. Rather, these embodiments are provided so that this disclosure will be thorough and complete, and will fully convey the scope of present inventive concepts to those skilled in the art. It should also be noted that these embodiments are not mutually exclusive. Components from one embodiment may be tacitly assumed to be present/used in another embodiment.

The following description presents various embodiments of the disclosed subject matter. These embodiments are presented as teaching examples and are not to be construed as limiting the scope of the disclosed subject matter. For example, certain details of the described embodiments may be modified, omitted, or expanded upon without departing from the scope of the described subject matter.

The term “non-linear device” is used in a non-limiting manner and, as explained below, can refer to any type of non-linear electronic device including, without limitation, a PA, a D/A amplifier, an optical amplifier, a cable TV (CATV) amplifier, etc. whose output includes non-linear distortion.

The following explanation of potential problems with some approaches is a present realization as part of the present disclosure and is not to be construed as previously known by others.

Next generation wireless communications may include two or more carrier combining together with wide bandwidths, which may present additional challenges for both non-linear device and/or DPD behavior modeling (e.g., 4G LTE-A and 5G products). Modification of non-linear device and/or DPD behavior modeling of existing approaches may be needed to fulfill requirements of both the Federal Commission Committee (FCC) and 3rd Generation Partnership Project (3GPP). Sec e.g., F. M. Ghannouchi and O. Hammi, “Behavioral modeling and predistortion,” IEEE Microwave magazine, vol. 10, no. 7, pp. 52-64, 2009; S. Tehrani, H. Cao, S. Afsardoost, T. Eriksson, M. Isaksson, and C. Fager, “A comparative analysis of the complexity/accuracy tradeoff in power amplifier behavioral models,” IEEE Trans. Microw. Theory Techn., vol. 58, no. 6, pp. 1510-1520, 2010; D. R. Morgan et al., “A generalized memory polynomial model for digital predistortion of RF power amplifiers,” IEEE Trans. Signal Process., vol. 54, no. 10, pp. 3852-3860, 2006; F. Mkadem and S. Boumaiza, “Physically inspired neural network model for RF power amplifier behavioral modeling and digital predistortion,” IEEE Trans. Microw. Theory Techn., vol. 59, no. 4, pp. 913-923, 2011; M. Bhuyan and K. K. Sarma, “Learning aided behavioral modeling and adaptive digital predistortion design for nonlinear power amplifier,” IEEE Sensors Journal, vol. 16, no. 16, pp. 6167-6174 Aug. 2016.

Although MP and GMP may provide sufficient modeling performance under static traffic, performance of MP and GMP may decrease (e.g., significantly decrease) due to dynamic traffic. Performance may degrade even more when long-term memory effects are considered. Performance may degrade because, generally, polynomial fitting may only be applicable for signals in a small dynamic range, and polynomial fitting may only be capable of dealing with short-term memory effects. For example, performance of non-linear device and/or DPD behavioral modeling considering polynomial based algorithms, such as MP and GMP, under dynamic traffic even without long-term memory effects may be significantly degraded (e.g., more than 10 dB in terms of normalized mean squared error (NMSE)), as discussed further herein. Either the same GMP or MP process may be applied for each power level, or an averaging process may be considered to keep the same performance under dynamic traffic compared to the static traffic. Using the same process for each power level, however, may require large computational complexity and/or memory resources. Meanwhile, an averaging process with a GMP or MP process may significantly degrade the performance. Scc e.g., Y. Guo, C. Yu and A. Zhu, “Power adaptive digital predistortion for wideband RF power amplifiers with dynamic power transmission,” IEEE Trans. Microw. Theory Techn., vol. 63. No. 11, pp. 1-13. 2015; S. Dalipi, S. Hamrin and T. Johansson, “Digital predistortion of non-linear devices” U.S. patent application Ser. No. 13/988,533, August 2017.

Long term memory effects can include effects dependent on memory of the input signal; the memory being an order of magnitude, or more, longer than the inverse of the input signal bandwidth. Thus, even if GMP and/or MP approaches attempted to consider dynamic traffic with or without long-term memory effects, such approaches may incur heavy computational complexity and/or memory resource demands. Additionally, such approaches may not be easy to deploy, may not sufficiently improve energy efficiency in non-linear device and/or DPD behavior modeling, and may be usable only within a narrow power range (e.g., which may be a limiting factor in their applicability since they may not address dynamic traffic effects).

A ML based approach does not appear to exist in the context of non-linear device (e.g., a PA) and/or DPD behavioral modeling under dynamic traffic conditions. Sec e.g., Sheppard, “Tree-based machine learning algorithms: Decision trees, random forests, and boosting” CreateSpace Ind. Publish. Platform, 2017; J. Song. J. Zhao, F. Dong, J. Zhao, Z. Qian, and Q. Zhang, “A novel regression modeling method for PMSLM structural design optimization using a distance-weighted KNN algorithm,” IEEE Transactions on Industry Applications, vol. 54, no. 5, pp. 4198-4206 Sep. 2018; M. A. Nielsen, “Neural networks and deep learning” Determination Press, 2018.

Certain aspects of the disclosure and their embodiments may provide solutions to these or other challenges.

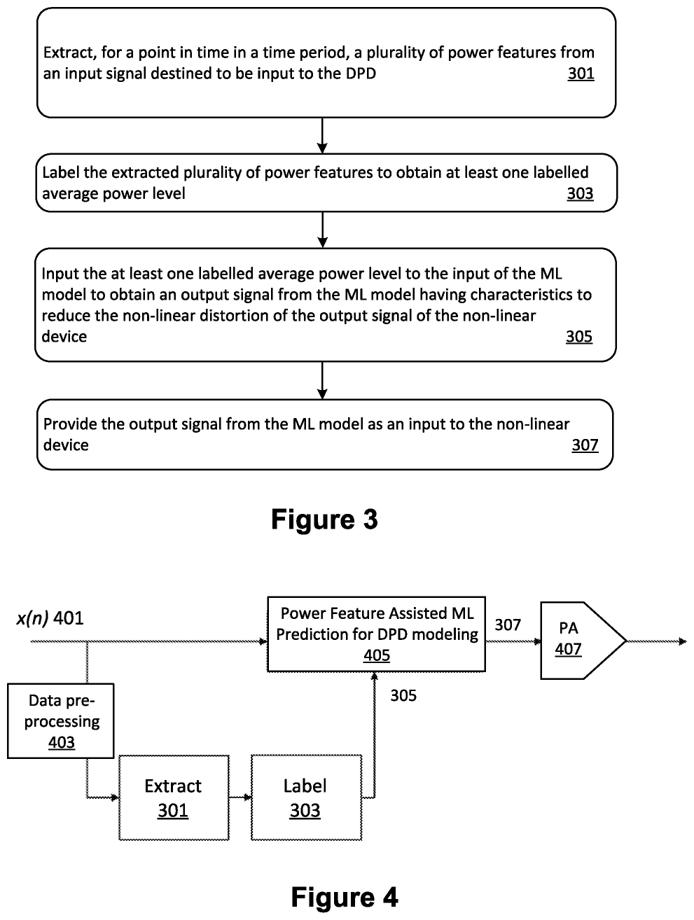

FIG. 3 is a flowchart illustrating a computer-implemented method performed by a device (e.g., QQ110, QQ112, QQ200, QQ300, QQ500 as discussed further herein) configured with a power feature aided ML model that models the behavior of DPD to reduce non-linear distortion of an output signal of a non-linear device. With “DPD” we mean any clement, device, module, processor, system, etc. capable of performing a Digital Predistortion, or the Digital Predistortion itself. The method includes extracting (301), for a point in time in a time period, a plurality of power features from an input signal destined to be input to the DPD. The method further includes labelling (303) the extracted plurality of power features to obtain at least one labelled average power level. The method further includes inputting (305) the at least one labelled average power level to the input of the ML model to obtain an output signal from the ML model having characteristics to reduce the non-linear distortion of the output signal of the non-linear device. The method further includes providing (307) the output signal from the ML model as an input to the non-linear device.

Potential advantages provided by certain embodiments of the present disclosure may include that, based on the inclusion of power feature aided ML modeling of a behavior of the DPD and/or the non-linear device, dynamic traffic effects and long-term memory effects may be considered without significant additional computational complexity or memory resource demands. Additionally, improved computational ability of the method of the present disclosure may aid with ease of deployment, both for offline training/online prediction and for online training/online prediction. A consequence of offline training also may include improved energy efficiency in the non-linear device and/or DPD behavior modeling.

Thus, the inclusion of the power feature aided ML model may allow modeling on a realistic environment that includes consideration of dynamic traffic and with or without long-term memory effects, as discussed further herein.

In a communication system, power levels of a transmitted signal may be varied in different time slots due to dynamic traffic effects. The method of some embodiments includes power feature extraction (301) to provide a power level(s) according to the input signal to be inputted to the DPD, as illustrated in FIG. 4. FIG. 4 is a block diagram illustrating power feature assisted ML prediction for DPD behavior modeling in accordance with some embodiments. Input signal x(n) 401 is pre-processed 403 (e.g., complex-valued signals are converted to real signals). Power features are extracted 301 from the input signal 401 to obtain a power level(s) p(n). The power level(s) are then represented with different labels 303, and are input to a power feature assisted ML model 405 (e.g., a GB/XGB model) for prediction. At time n, power feature extraction (301) can be generally expressed as:

$$p ( n ) = E ( [ x ( n - N ) , x ( n - N + 1 ) , … , x ( n ) ] )$$

where E is a function (e.g., a filter) that performs power feature extraction, as discussed further herein, for a time period N (e.g., from n−N to n).

It is noted that, in some embodiments, the power level p(n) is not just relevant to current input, but also is relevant to historical input (that is, previous data in the time period). N represents the maximum memory length considered in the model. In some embodiments, the input signal further comprises a historical input signal from a filter in the power feature extraction. Further, in some embodiments, the extracting (301) is repeated for additional points in time in the time period.

In some embodiments, the filter is used to adapt to different effects and different memory length. In some embodiments, the power feature extraction (301) comprises a plurality of different memory lengths, and the labelling (303) comprises applying at least one filter to the extracted plurality of power features to obtain an average power. The filter adjusts for differences in the extracted plurality of power features and differences in the plurality of different memory lengths for power feature extraction.

While some embodiments discussed herein are explained in the non-limiting context of a power feature extraction applied by a filter, the invention is not so limited and includes any other method for power feature extraction.

In some embodiments, the at least one filter comprises at least one a moving-average (MA) filter, an exponential moving-average (EMA) filter, and autoregressive (AR) filter, and autoregressive moving-average (ARMA) filter, and a symbol-based (SB) filter.

A MA filter can be expressed as follows, where αᵢ is the coefficients. In general,

$${a}_{i} = \frac{1}{N} .$$

$$p ( n ) = {\sum }_{i = 0}^{N} {a}_{i} {\vert x ( n - i ) \vert}^{2}$$

An EMA filter is a special case of MA filter. The coefficient αᵢ=e⁻ⁱ in the EMA filter, namely

$$p ( n ) = {\sum }_{i = 0}^{N} {e}^{- i} {\vert x ( n - i ) \vert}^{2}$$

To consider long-term memory effects, an AR filter can be used, which can be given by

$$p ( n ) = {a}_{0} {\vert x ( n ) \vert}^{2} + {\sum }_{i = 1}^{N} {b}_{i} p ( n - i )$$

In some embodiments, the filter is an autoregressive moving-average (ARMA) filter that is a combined AR filter and MA filter, which may provide a more powerful filter, which can be expressed as

$$p ( n ) = {\sum }_{i = 0}^{N} {a}_{i} {\vert x ( n - i ) \vert}^{2} + {\sum }_{i = 1}^{N} {b}_{i} p ( n - i )$$

In some embodiments, the filter is a symbol-based (SB) filter. As referenced herein, some modern communication systems are built on OFDM or filtered-OFDM. Each OFDM symbol can have very different power levels. Power can be calculated on the scale of OFDM symbols, not on the scale of samples, which can accommodate the inherited characteristics from OFDM modulated signals. The power level of symbol n can be expressed as

$$p ( n ) = {\sum }_{i ∈ 𝒜} {c}_{i} {\vert x ( i ) \vert}^{2}$$

where, [symbol] indicates the samples in one OFDM symbol. Multiple symbols can be accumulated to include even longer memory effects.

In some embodiments, for the DPD and/or non-linear device behavior modeling, a period with fixed average power can be considered as one power level which can be labeled with the same power feature for the ML model. A different number of power levels can be considered based on the average power. For example, in experimental results of an example embodiment, five different power levels with five power features for each data set were applied. It is noted that different time durations/number of samples can be also considered instead of a same time duration for different power levels. That is, the power feature does not depend on the duration of a time period, but rather works for a same or different time durations for the power levels. Thus, in some embodiments, the at least one labelled average power level comprises a filtered average power level that is labelled as one power level; and, in some embodiments, the time period comprises a plurality of different time periods having different durations. In some embodiments, the time period comprises a plurality of different time periods having different durations, and the extracting (301) is repeated and identifies a power feature from the input signal over at least one different time period having a different duration.

It is noted that the power feature can have various formulations, which can be generally written as a function of power levels p in dB:

$$F = f ( p )$$

In an example embodiment, a step function can be used to represent different power features as follows:

$$f ( p ) = {\sum }_{i = 0}^{n} {α}_{i} {χ}_{{A}_{i}} ( p ) ,$$

where n≥0, aᵢ and Aᵢ are constant number and intervals, respectively. χ_{A} is the indicator function of A

$${χ}_{A} ( x ) = \{ \begin{matrix}1 , & if x ∈ A \\ 0 , & if x ∉ A\end{matrix} .$$

This function can be designed based on a working status of the PA. For example, if a PA relatively works in the linear region, this function can be a linear function of 10^{p/20}, otherwise a nonlinear function can be used.

In some embodiments, the ML model comprises a tree-based power feature aided gradient boosting, GB, model and/or power feature aided extreme gradient boosting, XGB, model. Modifications to a GB/XGB ML model to provide a power feature aided ML model for applicability to, e.g., dynamic traffic may provide robustness under dynamic traffic conditions, including with or without long-term memory effects. As a consequence, and as discussed further herein, some embodiments of the method of the present disclosure may have about the same performance compared to static traffic without long-term memory effects with small additional (e.g., ignorable) complexity. A single predictor may be important to model a non-linear device and/or DPD at different power levels to keep the performance about the same compared to a single power level. Instead of fitting and saving separate networks for each power level in a training stage, in some embodiments, power feature extraction and power labeling is used in power feature aided GB and XGB based modeling approaches, as discussed further herein.

While some embodiments discussed herein are explained in the non-limiting context of a power feature aided ML agent comprising a GB and/or an XGB model, the invention is not so limited and includes any ML agent configured to perform operations according to embodiments disclosed herein.

GB regression, which provides a prediction model in the form of an ensemble of weak prediction models, may be considered as one of the best tree-based ML approaches. To increase performance of tree-based methods, boosting as an optimization algorithm on a suitable cost function is applied. XGB regression is a special version of the GB model that may deliver more accurate assumptions (e.g., much more accurate) by using the strengths of second order derivatives of the loss function, L1 and L2 regularization and parallel computing.

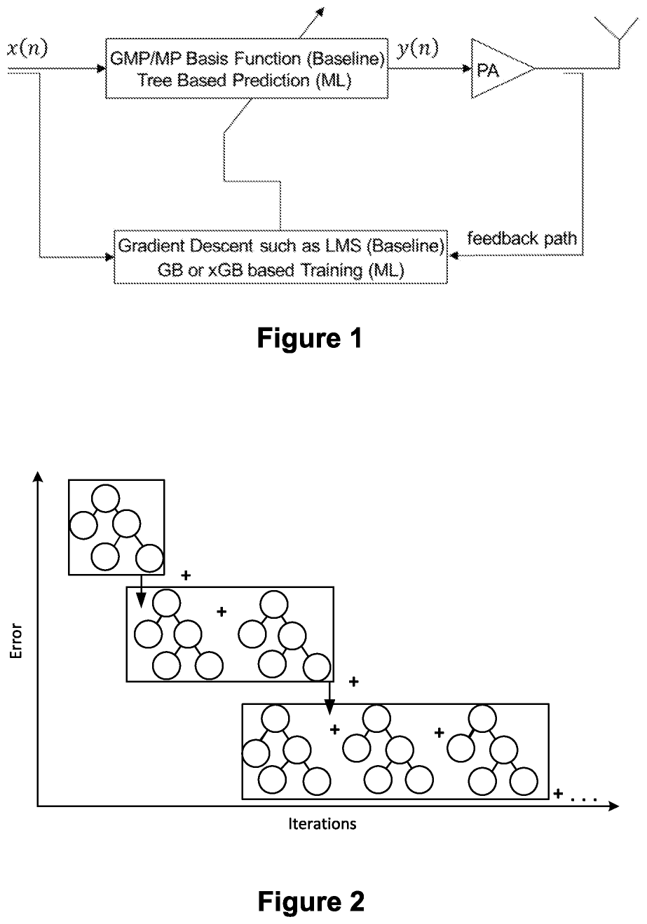

PA and/or DPD behavior modeling may be used to help compensate for nonlinearity effects in transmission. FIG. 1 is a block diagram illustrating a DPD process using (i) a GMP/MP approach, and (ii) GB and XGB based model with online implementation. In FIG. 1, in a baseline process, a basis function (that is, coefficients) is updated based on a gradient descent-based learning or adaptation for GMP/MP. In ML-based approaches, tree based prediction is updated based on GB or XGB based training.

For modeling in GMP/MP, PA input and output signals may be complex due to that complex data have to be considered. However, ML algorithms work with real-valued signals in contrast to GMP/MP based approaches. Due to that, complex-valued signals are converted to real signals in a matrix format considering separated real and imaginary values together with memory cases in a ML based approach as seen in tested example embodiments (as discussed further herein). Then, power feature aided ML techniques (e.g., GB/XGB) are applied to data measured from an RF PA, and performance is compared with conventional MP/GMP based modeling techniques in terms of normalized mean square error (NMSE) and adjacent channel error power ratio (ACEPR).

Traditional decision trees (DTs), which can be considered as both a classification and regression method, can separate input space to different parts. In some embodiments, the real and imaginary value of the samples are split considering the PA memory effects and, in this way, model output is dependent on both the current and memory stages. In some embodiments, automatic feature selection, such as an optimal splitting feature and threshold, may be an important feature of DT during a training phase. With an optimal splitting feature and threshold, a nonlinear relationship may be modeled that can consider long-term memory effects.

However, only a few features may be addressed using a single DT and full characterization of PA behavior may not be achieved. To address such a disadvantage of a single DT based approach, in some embodiments, the method includes a GB/XGB regression-based model, which may improve lincarization performance in PA and DPD behavior modeling. FIG. 2 is a schematic illustrating GB regression in terms of algorithm iterations as an ensemble of DTs in accordance with some embodiments of the present disclosure. Instead of having one tree, the method predicts an outcome based on an additive regression model that uses DT as a weak learner to fit a parameterized function (base learner) upon current “pseudo” residuals obtained at each iteration by optimizing regression loss (e.g., least squares, absolute error, etc.). “Pseudo” residuals refer to minimization of the gradient of a loss function with respect to values of the regression model at each training data point for the current step. Introduction of randomization in the process of training data set selection may allow improvement of accuracy and may reduce the possibility of overfitting. Additionally, this way of compiling a DT may allow minimization of errors at each next step and, therefore, such a boosting regressor may be more reliable and robust than a single DT regressor.

In terms of specifically modeling a behavior of a PA and/or DPD, based on using a power feature aided ML model (such as a power feature aided GB/XGB model), the behavior modeling of a PA and/or DPD includes complex and diverse cross terms to address memory effects to compensate for distortion of wideband signals. Existing traditional tree models, such as decision trees, may only model interactions including selected splitting feature, which may include limited cross terms. In contrast, a boosting approach of the present disclosure may improve accuracy with aggregation of several models as illustrated, for example, in FIG. 2.

Additionally, due to the piecewise structure, tree-based ML approaches such as GB and XGB, may have low power consumption (e.g., higher energy efficiency) because, instead of a full model, each input data sample can be processed with the related nonlinear operators. As a consequence, the method of the present disclosure, may increase the degrees of freedom in the modeling and at the same time, may create more diversity in the basis functions. Thus, in some embodiments, the power feature aided GB and XGB based ML method may achieve better modeling accuracy (e.g., very high accuracy) with less needed memory (e.g., hardware) resources and lower power consumption.

Some embodiments of the present disclosure include offline implementation; and some embodiments include online implementation.

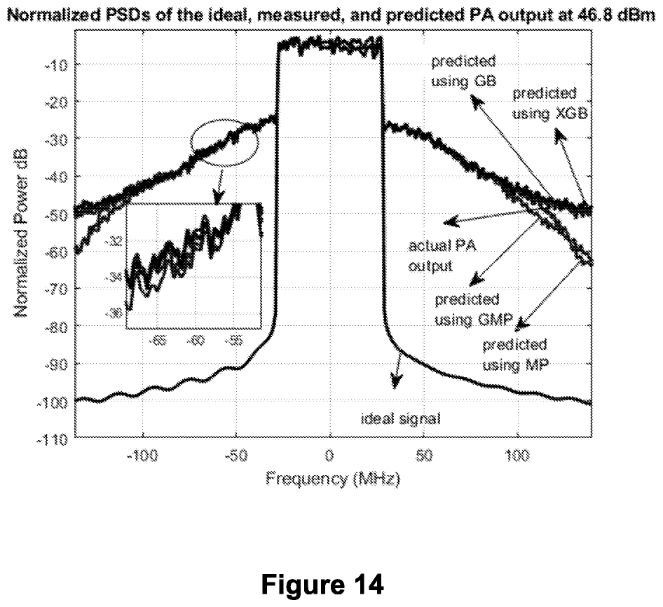

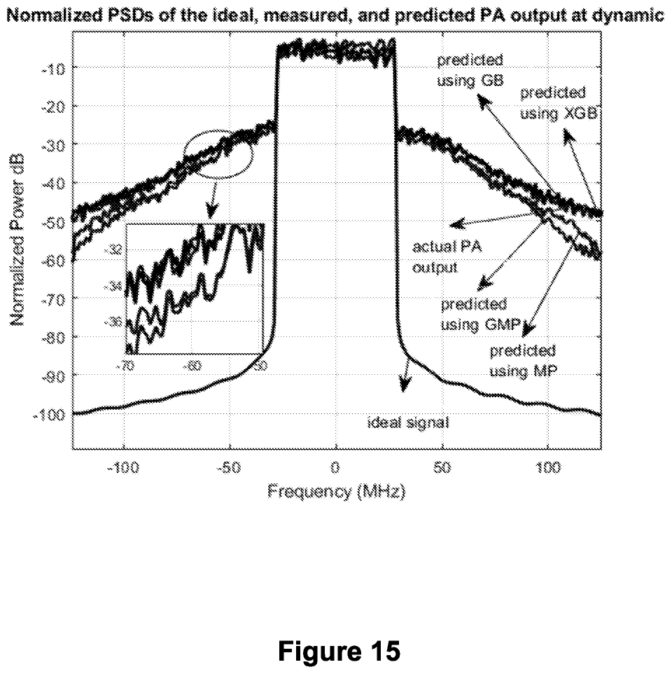

In some embodiments that include offline implementation, PA and/or DPD training is completed offline in different periods such as once in a week, month, year, and the saved network is used for the prediction considering any test signals. As discussed further herein with reference to Tables I-IV and FIGS. 14 and 15, performance and computational complexity analysis are evaluated for an example embodiment of offline implementation. It is noted that similar computational complexity analysis may be done for online implementation and similar results may be expected.

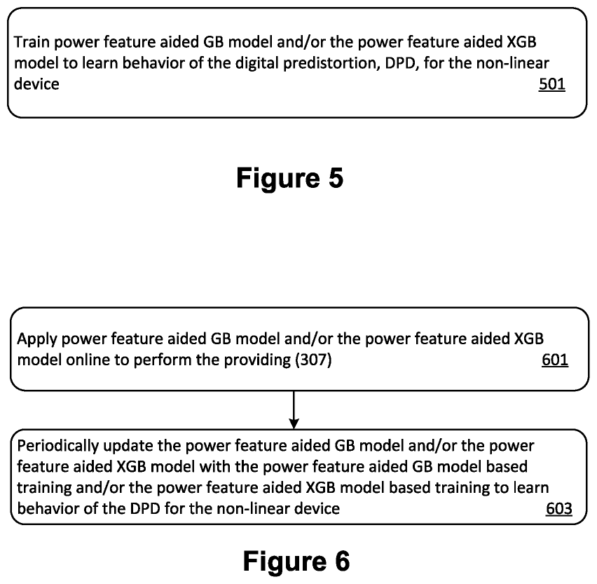

FIG. 5 is a flow chart illustrating optional operations of a device for training online or offline in accordance with some embodiments of the present disclosure. FIG. 7 is a block diagram illustrating an example embodiment of an offline implementation of PA and DPD behavior modeling (training) using power feature aided GB and/or XGB models.

Referring to FIG. 7, in some embodiments, PA and DPD behavior modeling are considered in the same procedure for offline training. Baseband I/Q component samples can be generated 701 with a signal generator and provided as input signal 401 with the corresponding power and carrier frequency. The generated signals can consider both the static and dynamic traffic effects. Because the power feature aided ML model works with real-valued signals, the complex-valued signals are converted with data pre-processing 403 to real signals considering memory cases. A matrix formulation may be adopted with the real and imaginary parts of the complex input and output signals written separately. In some embodiments, the ML model comprises a GB and/or XGB model. Tree-based algorithms such as GB and XGB do not support multiple outputs. Therefore, during training 701, separate real and imaginary training networks can be applied on the tree-based methods.

Power feature aided ML techniques (e.g., GB/XGB) are applied such that an output of DPD 703 corresponds to an “inverse” signal of PA 705 (that is a signal for compensating or helping to compensate for non-linear behavior of the PA 705). The DPD 703 output can be calculated with iterative learning controller (ILC) that tries to find a desired linear output. k determines the number of iterations and in the k-th iteration, an input uₖ(n) passes to the PA 705 and output yₖ(n) from PA 705 is produced after PA nonlinearity. In the ILC data acquisition, an error which is observed between the desired and actual output eₖ(n)=y_{d}(n)−yₖ(n) and the current input signal uₖ(n) are used to compute a new input uₖ₊₁(n) which is used for the next iteration. In general, the minimization of error eₖ(n) in the learning algorithm is targeted by the ILC in each iteration of the system. This process is iteratively repeated until reaching a target performance (e.g., the output signal from PA 705 is input to a spectrum analyzer 707).

In some embodiments, the training of FIGS. 5 and 7 includes training (501, 701) of the power feature aided GB model and/or the power feature aided XGB model to learn behavior of the DPD 703 for the non-linear device 705 or behavior of the non-linear device 705. In some embodiments, the input signal 401, destined to be input to the DPD, comprises a first input signal to the power feature aided ML model, and the training (501, 701) includes comparing the output signal from the power feature aided ML model with a target output signal and identifying an error based on the comparison (e.g., check spectrum 707). The training (501, 701) further includes, based on identifying the error, updating the first input signal 4011 to compute a new input signal 401, after n-iterations destined for the DPD for a next iteration. The training (501, 701) further includes iteratively repeating the extracting (operation 301 of FIG. 3), the labelling (operation 303 of FIG. 3), the inputting (operation 305 of FIG. 3), the providing (operation 307 of FIG. 3), the comparing, and the updating until the target output signal is approached. In some embodiments, as illustrated for example in FIG. 7, the training (501, 701) is performed offline a communications system.

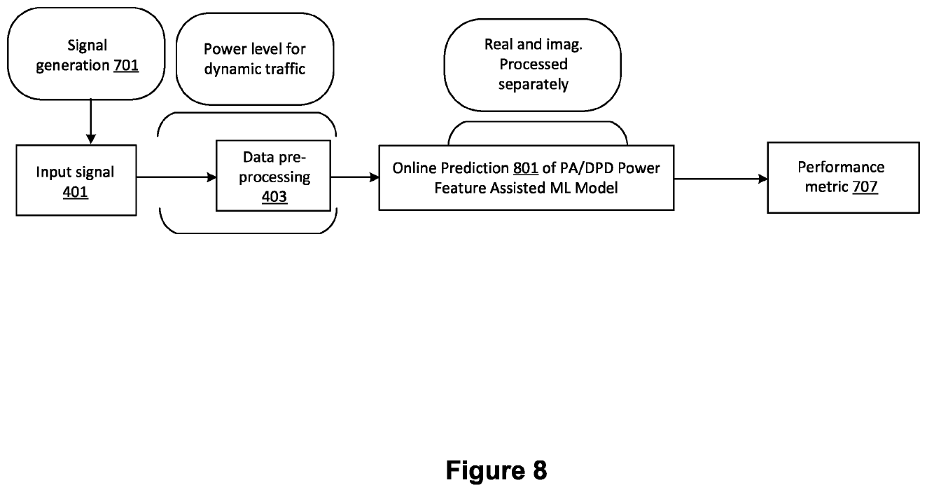

FIG. 8 is a block diagram illustrating an example embodiment of an online implementation of PA and DPD behavior modeling (prediction) using a power feature aided ML model (e.g., a GB and/or XGB model). In some embodiments, the method includes PA and/or DPD behavior modeling (prediction 801) using the power feature aided ML model. In some embodiments, the input signal 401, destined to be input to the DPD, is input to the power feature aided ML model, and the predicting (801) includes comparing the output signal from the power feature aided ML model with a target output signal and identifying an error based on the comparison (e.g., check spectrum 707). The predicting (801) further includes performing the extracting (operation 301 of FIG. 3) and the labelling (operation 303 of FIG. 3.

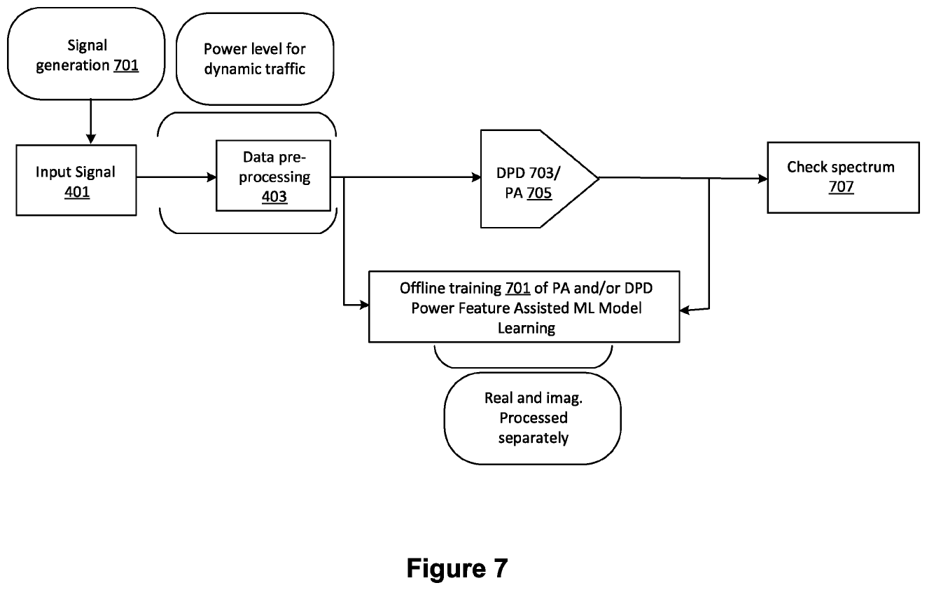

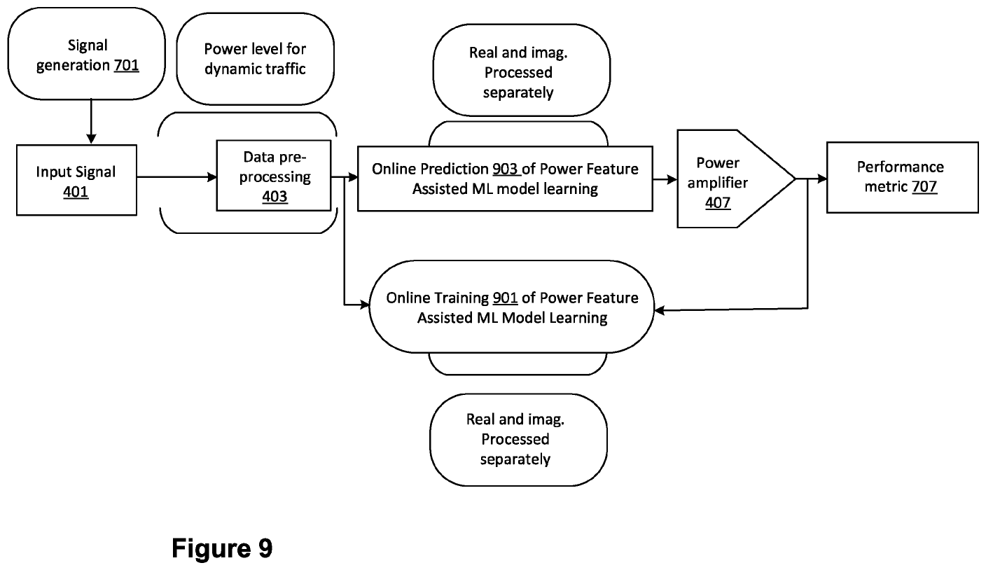

FIG. 6 is a flow chart illustrating optional operations of a device for training and prediction online in accordance with some embodiments of the present disclosure. FIG. 9 is a block diagram illustrating an example embodiment of an online implementations of power feature assisted ML based training and prediction (e.g., power feature aided GB and/or XGB based training and prediction.

Referring to FIG. 9, in some embodiments, during online training 901, PA and DPD behavior modeling are considered in the same procedure for online training. Baseband I/Q component samples can be generated 701 with a signal generator and provided as input signal 401 with the corresponding transmit power and carrier frequency. The generated signals can consider both the static and dynamic traffic effects. Because the power feature aided ML model works with real-valued signals, the complex-valued signals are converted with data pre-processing 403 to real signals considering memory cases. A matrix formulation may be adopted with the real and imaginary parts of the complex input and output signals written separately. In some embodiments, the ML model comprises a GB and/or XGB model. As discussed above, tree-based algorithms such as GB and XGB do not support multiple outputs. Therefore, during training 901, separate real and imaginary training networks can be applied on the tree-based methods.

Power feature aided ML techniques (e.g., GB/XGB) are applied such that an output of DPD training 901 corresponds to an “inverse” signal of PA 407 (that is a signal for compensating or helping to compensate for non-linear behavior of the PA 407). The DPD output from training 901 can be calculated with ILC that tries to find a desired linear output. k determines the number of iterations and in the k-th iteration, an input uₖ(n) passes to the PA 407 and output yₖ(n) from PA 407 is produced after PA nonlinearity. In the ILC data acquisition, an error which is observed between the desired and actual output eₖ(n)=y_{d}(n)−yₖ(n) and the current input signal uₖ(n) are used to compute a new input uₖ₊₁(n) which is used for the next iteration. In general, the minimization of error eₖ(n) in the learning algorithm is targeted by the ILC in each iteration of the system. This process is iteratively repeated until reaching a target performance (e.g., the output signal from PA 407 is input to a spectrum analyzer 707).

In some embodiments, the method of FIGS. 6 and 9 further includes applying (601) the power feature aided GB model and/or the power feature aided XGB model online to perform the providing (307). The method further includes periodically updating (603) the power feature aided GB model and/or the power feature aided XGB model with the power feature aided GB model based training and/or the power feature aided XGB model based training to learn behavior of the DPD for the non-linear device.

Potential further advantages provided by certain embodiments of the present disclosure may include that two approaches can be applied to, e.g., radio products with affordable effort. A first approach includes offline training and online prediction. The training can be performed in the production line with pre-defined training data. The resultant trees can be stored in database. Since the prediction may not need high computation, this approach can minimize the cost of application. A second approach includes online training and online prediction. The training can be performed periodically based on the data provided by the observation path. In the second approach, the training can follow the state of the non-linear device and extract state-of-the-art behavior. To reduce the computation, the periodicity can be enlarged, or the scale of trees can be decreased.

A potential further advantage provided by certain embodiments of the present disclosure may include that power feature aided GB and XGB based ML may improve energy efficiency in non-linear device and/or DPD behavior modeling with based on offline training in a longer time period that the repeating of the training may not be required in a shorter time period if the environment does not change often.

In some embodiments, the method includes PA and/or DPD behavior modeling (prediction 903) using the power feature aided ML model. In some embodiments, the input signal 401 is input to the power feature aided ML model, and the learning (901) includes comparing the output signal with a target output signal and identifying an error based on the comparison (e.g., check spectrum 707). The predicting (903) further includes performing the extracting (operation 301 of FIG. 3) and the labelling (operation 303 of FIG. 3). In some embodiments, as illustrated for example in FIG. 9, the predicting (903) is performed online a communications system.

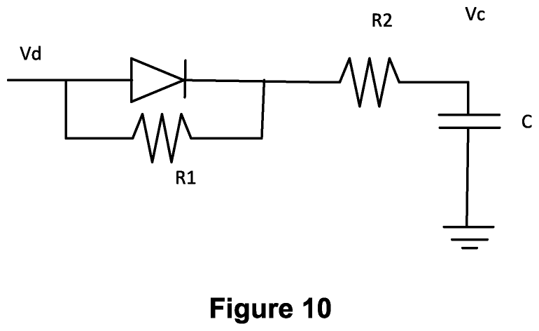

The method of some embodiments can also consider trapping effects. Trapping effects, which are generally related to material and processing conditions of a PA, correspond to different energy states. For example, trapping effects in gallium nitride (GaN) can occur at the gate and the drain of a PA (referred to herein as gate lag and drain lag, respectively). While compensation of trapping effects at gate lag may be straightforward, compensation of trapping effects at drain lag may be a challenge and may have impact on the behavior of the transistor. The method of the present disclosure can be used to include consideration of trapping effects (e.g., as modeled in the electron trapping circuit model of FIG. 10 in which the charge is controlled by the drain voltage (Vd)). Referring to FIG. 10, when voltage is positive, the diode of FIG. 10 acts as a short circuit due to behavior of the diode, otherwise the diode is an open circuit when the voltage is negative. Based on inclusion of two different resistors, different charge and discharge are observed at time-constants.

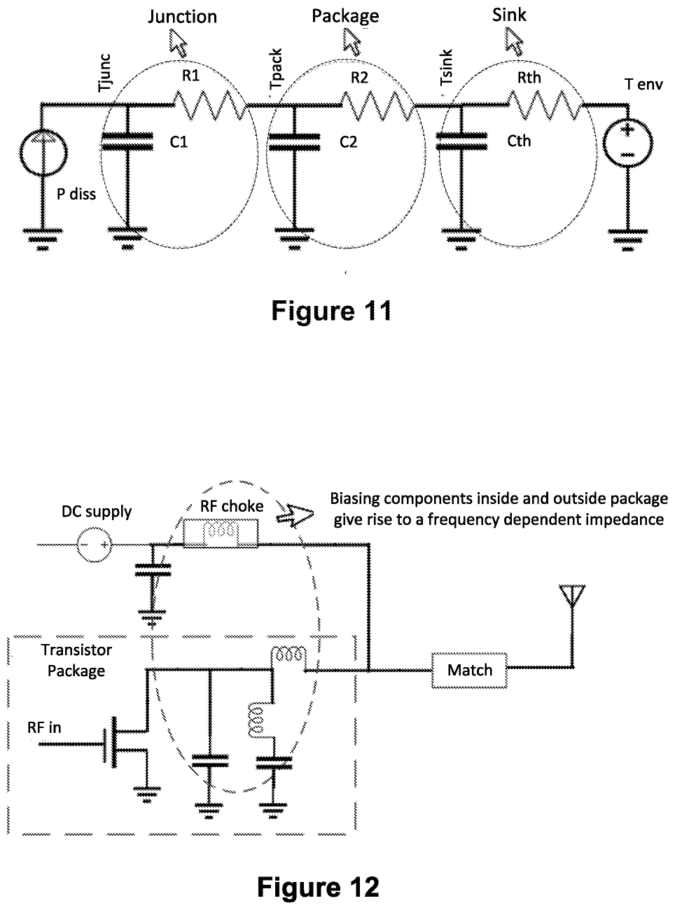

In addition to trapping effects, the method of some embodiments can also consider electron-thermal effects (e.g., as modeled in the circuit in FIG. 11). Referring to FIG. 11, temperature of the non-linear device can vary based on the power consumption on the transistor. As illustrated in FIG. 11, the heat flow source can spread through the junction, to the package, and to the sink. While constant temperature may be observed in the package and the sink of the non-linear device, when in operation, the temperature at the junction of the non-linear device may have high dependency on the thermal capacitance and conductivity of the transistor. It is noted that both the trapping and thermal diagrams of FIGS. 10 and 11. respectively, are models of a physical phenomenon (that is, such components are not actually present in the circuit). Transistor characteristics (e.g., especially drain current) can depend on the junction temperature, the instantaneous drain voltage, and the trapping states in the non-linear device, so the resulting voltages in the models impact the linearity of the non-linear device.

FIG. 12 is schematic illustrating a biasing circuit model for a PA. FIG. 12 illustrates a problem with a frequency varying impedance at low frequencies, causing low-frequency ripple on the Vdd, which in turn can affect linearity. Impedance variations as low as a few MHz may occur with quite long memory.

In some embodiments, the non-linear distortion is a result of at least one of (i) variation of power levels in input signals due to dynamic traffic conditions, (ii) trapping effects in the non-linear device, and (iii) electro-thermal effects in the non-linear device.

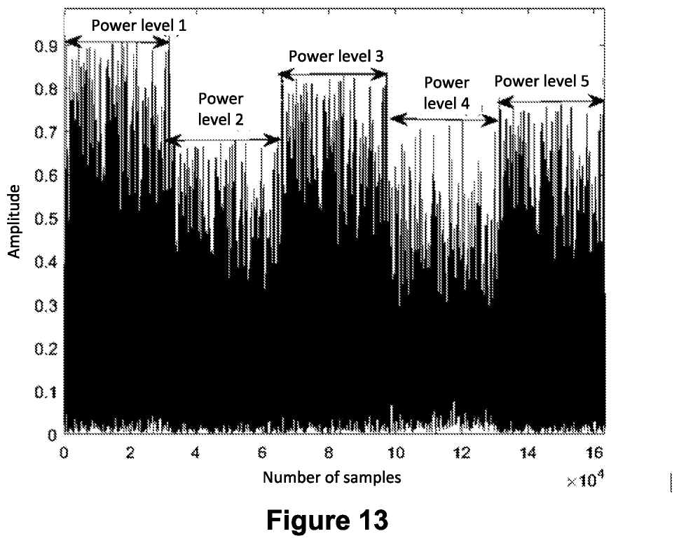

For example, in addition to trapping effects, electron-thermal effects, and frequency variant impedance as seen in the example circuit models in FIGS. 10, 11, and 12, respectively, variation on the power levels due to dynamic traffic as illustrated in FIG. 13 may create an additional challenge for non-linear device and/or DPD behavior modeling. Independent of trapping effects, electron-thermal effects, and frequency variant impedance, in some embodiments, the method includes power feature aided ML, which may improve modeling accuracy (as discussed further herein). By introducing a power feature aided ML model with long-term memory (including the average power feature), the DPD may counteract (or nearly counteract) the impact of dynamic traffic effects to produce a linear, near linear, or improvement in non-linearity in the output signal from the non-linear device. For example, consideration of dynamic traffic affects can be performed without having to explicitly include models of trapping effects and/or electron-thermal effects (e.g., FIGS. 10 and 11) in the DPD.

In some embodiments, the method further includes modeling a behavior of the non-linear device. That is the operations of the method discussed herein with respect to FIGS. 3-9 are applicable to modeling of behavior of the DPD and/or the non-linear device.

In some embodiments, the non-linear device comprises a power amplifier.

In some embodiments, the device (e.g., device QQ110, QQ112, QQ200, QQ300, QQ500 as discussed further herein) comprises a component in a radio unit of a base station or a component in a user equipment (e.g. such as an application specific integrated circuit (ASIC) or field programmable gate array (FPGA)). In some embodiments, the ASIC or the FPGA includes the DPD of the non-linear device.

As discussed herein, in general, ML models are designed to work with real-valued signals. In an example embodiment that was tested, a power feature aided ML model is adapted to handle complex-valued signals. The power feature aided ML model was applied to the data measured from an RF PA prototype, and the performance was compared to a conventional MP based technique in terms of NMSE and ACEPR, considering wideband 5G NR waveforms. In the case of PA behavior modeling, the input signal and output signal of the PA were measured from the PA prototype. In the case of DPD behavior modeling, the input signal and output signal of DPD were obtained by ILC, and subsequently the procedure for PA behavior modeling can be reused. The data was collected in different power levels for an example of dynamic traffic. The power feature aided ML model was trained and validated in different power levels.

Additionally, to evaluate robustness under dynamic traffic conditions with or without long-term memory effects, a power feature aided GB/XGB based model with small (e.g., nearly ignorable) extra complexity was considered and was found to be a robust signal processing technique. The tested example embodiments of a method using a power feature aided GB/XGB based model provides almost no performance degradation under dynamic traffic conditions compared to static traffic conditions (that is, about 10% extra computational complexity, as discussed further herein).

Referring again to FIG. 7, setup of ML model implementation for the testing is discussed further. A test setup included a signal generator (SG) (e.g., signal generator 701) and spectrum analyzer (SA) (e.g., for checking 707 spectrum) with MATLAB as the host-processor and PA. Baseband I/Q component samples were generated 701 in the Keysight SG and fed as input signals 401 to a PA with corresponding transmit power and carrier frequency. The PA output RF signal was then input to the Keysight SA to check the quality of the signal. The generated signals considered both static and dynamic traffic effects and were arranged based on memory effects in order to compare with conventional MP and GMP algorithms. Additionally, as referenced herein, due to that ML models work with real-valued signals, the complex-valued signals were converted (with data pre-processing 403) to real signals considering memory cases.

Performance of the experiments was evaluated using NMSE and ACEPR metrics using MATLAB. Information for mathematical models for both NMSE and ACEPR is discussed further herein.

The signal used in the experiments was generated according to new radio (NR) base station (BS) radio transmission and reception standards. The wide band signal with 60 MHz included nonlinearity effects. It is noted that PA behavior modeling under both static and dynamic traffic without long-term memory effects was considered as an example case in the experiments. However, it may be expected that performance of DPD behavior modeling that also including long-term memory effects may be similar.

In the experiments, to evaluate performance of the different behavioral modeling techniques, NMSE and ACEPR were used. NMSE evaluated full-band modeling accuracy of the PA and DPD behavioral models, and can be defined as

$${NMSE}_{dB} = 10 {log}_{10} \frac{{\sum }_{n = 1}^{N} {\vert {e}_{model} [ n ] \vert}^{2}}{{\sum }_{n = 1}^{N} {\vert {y}_{m e a s} [ n ] \vert}^{2}}$$

where e_{model}[n]=yₘₑₐₛ[n]−y_{model}[n] is the error signal between the measured signal and the predicted signal. On the other hand, ACEPR evaluated only the out-of-band modeling performance, computing a ratio between the error signal power over an adjacent channel and the desired channel power of the measured signal (Pₑᵣᵣₒᵣ^{adj} and Pₘₑₐₛ^{ch}), as

$${ACEPR}_{dB} = 10 {log}_{10} \frac{{P}_{e r r o r}^{adj}}{{P}_{m e a s}^{ch}} .$$

Training and prediction stages were considered separately in the experiments, as illustrated in FIGS. 7 and 8 under offline implementation. The training networks of power feature aided GB and XGB based ML methods were applied once and saved for the future test signals. In the data processing stage, the different training and test datasets were considered with the number of samples N=32,768 for each power level. A reason for this process was to capture two uncorrelated pieces of the dataset because if there is a strong correlation between training and test data, the performance of the PA behavior modeling may be inaccurate. Five different power levels corresponding to 46.8 dBm, 45.8 dBm, 45 dBm, 44.5 dBm, and 44 dBm in the output of the PA were applied as the input signals.

While a maximum depth of 4 and 2000 number of estimators were chosen with a 0.05 learning rate in a GB regression method, the maximum depth and number of estimators were 10 and 1000 with a 0.03 learning rate in XGB in the experiments. For an MP model to be used in a comparison with the GB/XGB based-models, polynomial order P=7 (with odd orders only considered) and memory order M=4 were used, while for a GMP model, aligned signal term Kₐ=7, envelope term Lₐ=4, lagging envelope terms K_{b}=5, L_{b}=3, G_{b}=2, and leading envelope terms K_{c}=L_{c}=G_{c}=0 were used (see e.g., D. R. Morgan et al., “A generalized memory polynomial model for digital predistortion of RF power amplifiers,” IEEE Trans. Signal Process., vol. 54, no. 10, pp. 3852-3860, 2006). Similarly, M=4 was used in all the ML algorithms in the experiments. Once the training stage of FIG. 7 was completed, the different test signals were applied in the prediction stage in FIG. 8 using the saved fitting network. Finally, the NMSE and ACEPR were calculated after forming complex signals from the real-valued predictor outputs.

In the experiments, two cases were considered to evaluate performance of an example embodiment of the present disclosure using the power feature assisted ML-based model (GB and XGB in the experiments) versus conventional polynomial-based models (MP and GMP): (i) a single power level near the saturation level of the PA; and (ii) a single predictor at 5 different output power levels of the PA, were considered. The results are provided in Tables I and II herein, respectively. In the second case, instead of fitting and saving separate networks for each power level in the training stage, power feature extraction and power labeling as discussed herein was applied in power feature aided GB and XGB based ML models. Accordingly, the predictor's computational complexity was decreased, as discussed further herein. It is noted that one NMSE and one ACEPR value are shown in Table II for the case of dynamic traffic effects and that the single predictor was applied to obtain the performance under combination/merging of five different power levels.

The power spectral densities (PSDs) of the PA input, and the actual and predicted PA output using MP and GMP in comparison with power feature aided GB/XGB oriented ML models of the present disclosure, considering a 60 MHz NR input signal and a BS PA operating at 46.8-dBm (static traffic) and five different powers (dynamic traffic) are shown in FIGS. 14 and 15, respectively.

As seen in both FIG. 14 (under static traffic) and FIG. 15 (under dynamic traffic), there was behavior difference on PA behavior modeling considering MP and GMP both in-band and out-of-band (adjacent channel) parts. On the contrary, the behavior of power feature aided GB and XGB based models were similar in FIGS. 14 and 15. As discussed further herein, the numerical values for both NMSE and ACEPR are given in the following Tables I and II.

TABLE I
COMPARISON OF NMSE AND ACEPR OF POWER
FEATURE ASSISTED ML-BASED METHOD VERSUS
POLYNOMIAL BASED MODELS FOR A BASE
STATION PA USING STATIC TRAFFIC

| Machine Learning and Polynomial based Models | NMSE | ACEPR |
|---|---|---|
| Memory Polynomial | −28.0453 | −37.0170 |
| Generalized Memory Polynomial | −30.1372 | −37.3938 |
| Gradient Boosting | −25.7720 | −37.6548 |
| Xtreme Gradient Boosting | −25.9644 | −36.8727 |

TABLE II
COMPARISON OF NMSE AND ACEPR OF POWER
FEATURE ASSITED ML-BASED METHOD VERSUS
POLYNOMIAL BASED MODELS FOR THE BASE
STATION PA USING DYNAMIC TRAFFIC

| Machine Learning and Polynomial based Models | NMSE | ACEPR |
|---|---|---|
| Memory Polynomial | −17.9098 | −35.2973 |
| Generalized Memory Polynomial | −18.0425 | −35.2280 |
| Gradient Boosting | −25.2728 | −37.0028 |
| Xtreme Gradient Boosting | −25.8454 | −37.0513 |

Based on the results shown in Tables I and II, power feature aided GB and XGB based ML model approaches were robust to dynamic traffic effects with ignorable additional complexity from the power feature. The MP based approaches were sensitive to dynamic traffic effects due to, e.g., additional processing that may cause large computational complexity and/or large memory resources. As seen in Tables I and II, while the NMSE performances of MP and GMP under static traffic (with 46.8 dBm power at PA output) were −28.04 dB and −30.13 dB, respectively, the NMSE performances of the same approaches under dynamic effects (with 46.8 dBm, 45.8 dBm, 45 dBm, 44.5 dBm, and 44 dBm power levels at PA output) are −17.90 dB and −18.04 dB. In contrast, NMSE performances of GB and XGB under static traffic were −25.77 dB and −25.96 dB, respectively, and the NMSE performances of the power feature aided GB and XGB under dynamic effects were −25.27 dB and −25.84 dB.

Thus, in the experiments, due to dynamic traffic effects, there was about 10 dB performance degradation in the MP and GMP models. In contrast, performance degradation in the power feature aided GB and XGB based ML model based approaches of the present disclosure were much smaller (e.g., ignorable) under dynamic traffic effects. Similarly, there was about 2 dB performance degradation in terms of ACEPR for the MP and GMP models. In contrast, the power feature aided GB and XGB ML based approaches of the present disclosure were much smaller (e.g., ignorable) as seen in Tables I and II. As a consequence, the method of the present disclosure may provide robust performance based on inclusion of a power feature aided ML model.

Computational complexity is now discussed further. In the literature, there may be limited computational complexity analysis of ML based models due to such approaches being considered as black box approaches. See e.g., Sheppard, “Tree-based machine learning algorithms: Decision trees, random forests, and boosting” CreateSpace Ind. Publish. Platform, 2017; T. Hastie, R. Tibshirani and J. Friedman, “The elements of statistical learning: Data mining, inference, and prediction” Springer Series, 2016; M. Mohri, A. Rostamizadeh and A. Talwalkar, “Foundations of machine learning” MIT Press, 2018. In the following Tables III and IV, n is the number of training samples, p is the number of features, and ntrees is the number of trees (for ML models based on various trees):

TABLE III
COMPUTATIONAL COMPLEXITY OF ML-BASED
MODELS UNDER STATIC TRAFFIC

| | Training | Prediction | Prediction |
|---|---|---|---|
| Machine Learning Models | (Parametric) | (Parametric) | (Numerical) |
| Gradient Boosting | npnₜᵣₑₑₛ | pnₜᵣₑₑₛ | 20000 |
| Xtreme Gradient Boosting | n²pnₜᵣₑₑₛ | pnₜᵣₑₑₛ | 10000 |

TABLE IV
COMPUTATIONAL COMPLEXITY OF ML-BASED
MODELS UNDER DYNAMIC TRAFFIC

| | Training | Prediction | Prediction |
|---|---|---|---|
| Machine Learning Models | (Parametric) | (Parametric) | (Numerical) |
| Gradient Boosting | n(p + 1)nₜᵣₑₑₛ | (p + 1)nₜᵣₑₑₛ | 22000 |
| Xtreme Gradient Boosting | n²(p + 1)nₜᵣₑₑₛ | (p + 1)nₜᵣₑₑₛ | 11000 |

Tables III (for static traffic) and Table IV (for dynamic traffic) illustrate computational complexity of GB and XGB based ML models considering parametric and numerical values in terms of real number of multiplications. As seen in the tables, the real number of multiplications (numerical values) is only considered for the prediction process because the training was done once and the same network was used in the prediction in the future. As further illustrated in Tables III and IV, the power feature aided ML-based method of the present disclosure may increase performance of the method under dynamic traffic effects, while having only about 10% additional computational complexity. As a consequence, the performance of power feature aided GB and XGB oriented ML models may be kept about the same under dynamic traffic effects compared to the static traffic condition, as illustrated in Tables I and II.

Additionally, some approaches, such as MP and GMP, may have extra processing for dynamic traffic effects that may result in extra significant computational complexity and/or memory resources. See e.g., Y. Guo, C. Yu and A. Zhu, “Power adaptive digital predistortion for wideband RF power amplifiers with dynamic power transmission,” IEEE Trans. Microw. Theory Techn., vol. 63. No. 11, pp. 1-13. 2015; J. Pedro et al., “A Review of Memory Effects in AlGaN/GaN HEMT Based RF PAS,” in 2021 IEEE MTT-S International Wireless Symposium (IWS), May 2021.

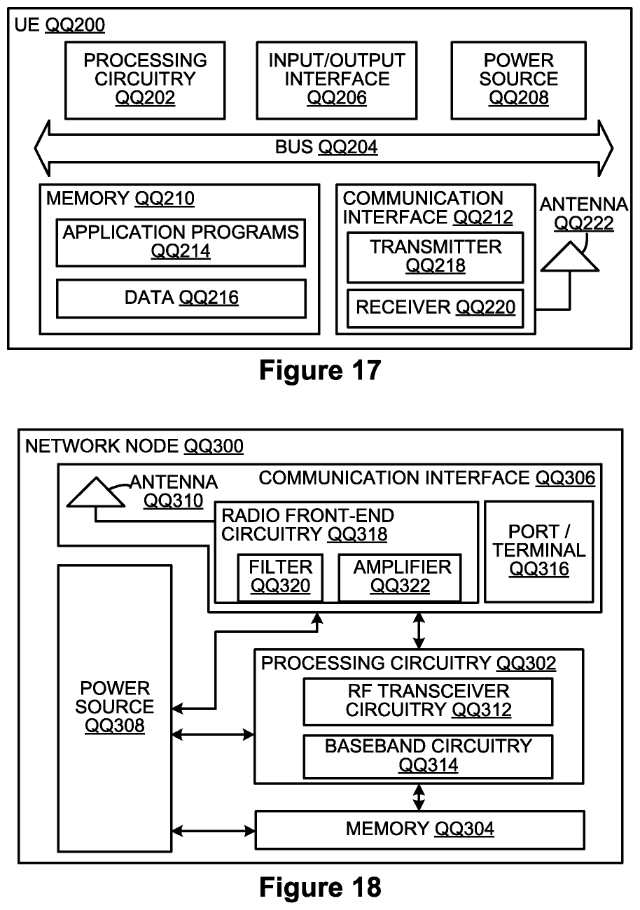

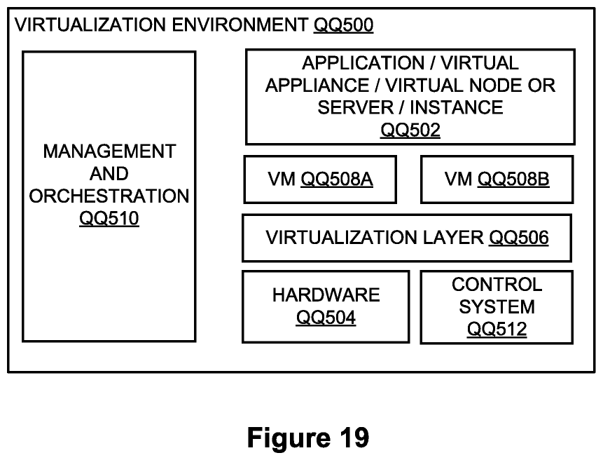

The device of various embodiments may be provided by a network node (e.g., QQ110, QQ300, QQ500) or a UE (QQ112, QQ200, QQ500) using the structure of the block diagrams of FIGS. 17-19. For example, modules (e.g., a power feature aided ML model) may be stored in at least one memory QQ210, QQ304, QQ508A, QQ508B of FIGS. 17-19, respectively, and these modules may provide instructions so that when the instructions of a module are executed by respective device processing circuitry (QQ202, QQ302,QQ508A, QQ508B, respectively), the processing circuitry performs respective operations of the flow charts of FIGS. 3, 5, and 6. According to some embodiments, the device and/or an clement(s)/function(s) thereof may be embodied as a virtual device/devices and/or a virtual machine/machines, e.g., as illustrated in FIG. 19.

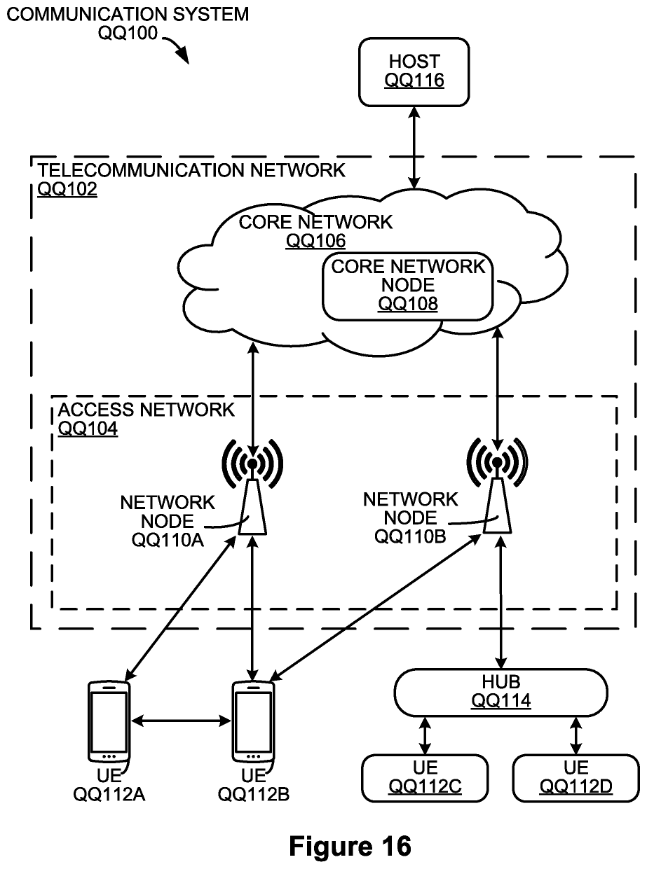

FIG. 16 shows an example of a communication system QQ100 in accordance with some embodiments.

In the example, the communication system QQ100 includes a telecommunication network QQ102 that includes an access network QQ104, such as a RAN, and a core network QQ106, which includes one or more core network nodes QQ108. The access network QQ104 includes one or more access network nodes, such as network nodes QQ110a and QQ110b (one or more of which may be generally referred to as network nodes QQ110), or any other similar 3rd Generation Partnership Project (3GPP) access node or non-3GPP access point. The network nodes QQ110 facilitate direct or indirect connection of a user equipment (UE), such as by connecting UEs QQ112a, QQ112b, QQ112c, and QQ112d (one or more of which may be generally referred to as UEs QQ112) to the core network QQ106 over one or more wireless connections.

Example wireless communications over a wireless connection include transmitting and/or receiving wireless signals using electromagnetic waves, radio waves, infrared waves, and/or other types of signals suitable for conveying information without the use of wires, cables, or other material conductors. Moreover, in different embodiments, the communication system QQ100 may include any number of wired or wireless networks, network nodes, UEs, and/or any other components or systems that may facilitate or participate in the communication of data and/or signals whether via wired or wireless connections. The communication system QQ100 may include and/or interface with any type of communication, telecommunication, data, cellular, radio network, and/or other similar type of system.

The UEs QQ112 may be any of a wide variety of communication devices, including wireless devices arranged, configured, and/or operable to communicate wirelessly with the network nodes QQ110 and other communication devices. Similarly, the network nodes QQ110 are arranged, capable, configured, and/or operable to communicate directly or indirectly with the UEs QQ112 and/or with other network nodes or equipment in the telecommunication network QQ102 to enable and/or provide network access, such as wireless network access, and/or to perform other functions, such as administration in the telecommunication network QQ102.

In the depicted example, the core network QQ106 connects the network nodes QQ110 to one or more hosts, such as host QQ116. These connections may be direct or indirect via one or more intermediary networks or devices. In other examples, network nodes may be directly coupled to hosts. The core network QQ106 includes one more core network nodes (e.g., core network node QQ108) that are structured with hardware and software components. Features of these components may be substantially similar to those described with respect to the UEs, network nodes, and/or hosts, such that the descriptions thereof are generally applicable to the corresponding components of the core network node QQ108. Example core network nodes include functions of one or more of a Mobile Switching Center (MSC), Mobility Management Entity (MME), Home Subscriber Server (HSS), Access and Mobility Management Function (AMF), Session Management Function (SMF), Authentication Server Function (AUSF), Subscription Identifier De-concealing function (SIDF), Unified Data Management (UDM), Security Edge Protection Proxy (SEPP), Network Exposure Function (NEF), and/or a User Plane Function (UPF).

The host QQ116 may be under the ownership or control of a service provider other than an operator or provider of the access network QQ104 and/or the telecommunication network QQ102, and may be operated by the service provider or on behalf of the service provider. The host QQ116 may host a variety of applications to provide one or more service. Examples of such applications include live and pre-recorded audio/video content, data collection services such as retrieving and compiling data on various ambient conditions detected by a plurality of UEs, analytics functionality, social media, functions for controlling or otherwise interacting with remote devices, functions for an alarm and surveillance center, or any other such function performed by a server.

As a whole, the communication system QQ100 of FIG. 16 enables connectivity between the UEs, network nodes, hosts, and devices. In that sense, the communication system may be configured to operate according to predefined rules or procedures, such as specific standards that include, but are not limited to: Global System for Mobile Communications (GSM); Universal Mobile Telecommunications System (UMTS); Long Term Evolution (LTE), and/or other suitable 2G, 3G, 4G, 5G standards, or any applicable future generation standard (e.g., 6G); wireless local area network (WLAN) standards, such as the Institute of Electrical and Electronics Engineers (IEEE) 802.11 standards (WiFi); and/or any other appropriate wireless communication standard, such as the Worldwide Interoperability for Microwave Access (WiMax), Bluetooth, Z-Wave, Near Field Communication (NFC) ZigBee, LiFi, and/or any low-power wide-area network (LPWAN) standards such as LoRa and Sigfox.

In some examples, the telecommunication network QQ102 is a cellular network that implements 3GPP standardized features. Accordingly, the telecommunications network QQ102 may support network slicing to provide different logical networks to different devices that are connected to the telecommunication network QQ102. For example, the telecommunications network QQ102 may provide Ultra Reliable Low Latency Communication (URLLC) services to some UEs, while providing Enhanced Mobile Broadband (eMBB) services to other UEs, and/or Massive Machine Type Communication (mMTC)/Massive IoT services to yet further UEs.

In some examples, the UEs QQ112 are configured to transmit and/or receive information without direct human interaction. For instance, a UE may be designed to transmit information to the access network QQ104 on a predetermined schedule, when triggered by an internal or external event, or in response to requests from the access network QQ104. Additionally, a UE may be configured for operating in single-or multi-RAT or multi-standard mode. For example, a UE may operate with any one or combination of Wi-Fi, NR (New Radio) and LTE, i.e. being configured for multi-radio dual connectivity (MR-DC), such as E-UTRAN (Evolved-UMTS Terrestrial Radio Access Network) New Radio-Dual Connectivity (EN-DC).

In the example, the hub QQ114 communicates with the access network QQ104 to facilitate indirect communication between one or more UEs (e.g., UE QQ112c and/or QQ112d) and network nodes (e.g., network node QQ110b).

Although the devices described herein may include the illustrated combination of hardware components, other embodiments may comprise computing devices with different combinations of components. It is to be understood that these devices may comprise any suitable combination of hardware and/or software needed to perform the tasks, features, functions and methods disclosed herein. Determining, calculating, obtaining or similar operations described herein may be performed by processing circuitry, which may process information by, for example, converting the obtained information into other information, comparing the obtained information or converted information to information stored in the device, and/or performing one or more operations based on the obtained information or converted information, and as a result of said processing making a determination. Moreover, while components are depicted as single boxes located within a larger box, or nested within multiple boxes, in practice, devices may comprise multiple different physical components that make up a single illustrated component, and functionality may be partitioned between separate components. For example, a communication interface may be configured to include any of the components described herein, and/or the functionality of the components may be partitioned between the processing circuitry and the communication interface. In another example, non-computationally intensive functions of any of such components may be implemented in software or firmware and computationally intensive functions may be implemented in hardware.

In certain embodiments, some or all of the functionality described herein may be provided by processing circuitry executing instructions stored on in memory, which in certain embodiments may be an RL agent and/or computer program product (e.g., including a power feature aided ML model) in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the device, but are enjoyed by the device as a whole, and/or by end users and a wireless network generally.

FIG. 17 shows a UE QQ200 in accordance with some embodiments. As used herein, a UE refers to a device configured with a power feature aided ML model that models a behavior of a DPD and/or a non-linear device to reduce non-linear distortion of an output signal of a non-linear device. Examples of a UE include, but are not limited to, a smart phone, mobile phone, cell phone, voice over IP (VoIP) phone, wireless local loop phone, desktop computer, personal digital assistant (PDA), wireless cameras, gaming console or device, music storage device, playback appliance, wearable terminal device, wireless endpoint, mobile station, tablet, laptop, laptop-embedded equipment (LEE), laptop-mounted equipment (LME), smart device, wireless customer-premise equipment (CPE), vehicle-mounted or vehicle embedded/integrated wireless device, etc. Other examples include any UE identified by the 3rd Generation Partnership Project (3GPP), including a narrow band internet of things (NB-IoT) UE, a machine type communication (MTC) UE, and/or an enhanced MTC (cMTC) UE.

A UE may support device-to-device (D2D) communication, for example by implementing a 3GPP standard for sidelink communication, Dedicated Short-Range Communication (DSRC), vehicle-to-vehicle (V2V), vehicle-to-infrastructure (V2I), or vehicle-to-everything (V2X). In other examples, a UE may not necessarily have a user in the sense of a human user who owns and/or operates the relevant device. Instead, a UE may represent a device that is intended for sale to, or operation by, a human user but which may not, or which may not initially, be associated with a specific human user (e.g., a smart sprinkler controller). Alternatively, a UE may represent a device that is not intended for sale to, or operation by, an end user but which may be associated with or operated for the benefit of a user (e.g., a smart power meter).

The UE QQ200 includes processing circuitry QQ202 that is operatively coupled via a bus QQ204 to an input/output interface QQ206, a power source QQ208, a memory QQ210 including the power feature aided ML model, a communication interface QQ212, and/or any other component, or any combination thereof. Certain UEs may utilize all or a subset of the components shown in FIG. 17. The level of integration between the components may vary from one UE to another UE. Further, certain UEs may contain multiple instances of a component, such as multiple processors, memories, transceivers, transmitters, receivers, etc.

The processing circuitry QQ202 is configured to process instructions and data and may be configured to implement any sequential state machine operative to execute instructions stored as machine-readable computer programs in the memory QQ210. The processing circuitry QQ202 may be implemented as one or more hardware-implemented state machines (e.g., in discrete logic, field-programmable gate arrays (FPGAs), application specific integrated circuits (ASICs), etc.); programmable logic together with appropriate firmware; one or more stored computer programs, general-purpose processors, such as a microprocessor or digital signal processor (DSP), together with appropriate software; or any combination of the above. For example, the processing circuitry QQ202 may include multiple central processing units (CPUs).

The memory QQ210 may be or be configured to include memory such as random access memory (RAM), read-only memory (ROM), programmable read-only memory (PROM), crasable programmable read-only memory (EPROM), electrically erasable programmable read-only memory (EEPROM), magnetic disks, optical disks, hard disks, removable cartridges, flash drives, and so forth. In one example, the memory QQ210 includes one or more application programs QQ214, such as an operating system, web browser application, a widget, gadget engine, or other application, and corresponding data QQ216. The memory QQ210 may store, for use by the UE QQ200, any of a variety of various operating systems or combinations of operating systems.

The memory QQ210 may be configured to include a number of physical drive units, such as redundant array of independent disks (RAID), flash memory, USB flash drive, external hard disk drive, thumb drive, pen drive, key drive, high-density digital versatile disc (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as tamper resistant module in the form of a universal integrated circuit card (UICC) including one or more subscriber identity modules (SIMs), such as a USIM and/or ISIM, other memory, or any combination thereof. The UICC may for example be an embedded UICC (eUICC), integrated UICC (iUICC) or a removable UICC commonly known as ‘SIM card.’ The memory QQ210 may allow the UE QQ200 to access instructions, application programs and the like, stored on transitory or non-transitory memory media, to off-load data, or to upload data. An article of manufacture, such as one utilizing a communication system may be tangibly embodied as or in the memory QQ210, which may be or comprise a device-readable storage medium.

The processing circuitry QQ202 may be configured to communicate with an access network or other network using the communication interface QQ212. The communication interface QQ212 may comprise one or more communication subsystems and may include or be communicatively coupled to an antenna QQ222. The communication interface QQ212 may include one or more transceivers used to communicate, such as by communicating with one or more remote transceivers of another device capable of wireless communication (e.g., another UE or a network node in an access network). Each transceiver may include a transmitter QQ218 and/or a receiver QQ220 appropriate to provide network communications (e.g., optical, electrical, frequency allocations, and so forth). Moreover, the transmitter QQ218 and receiver QQ220 may be coupled to one or more antennas (e.g., antenna QQ222) and may share circuit components, software or firmware, or alternatively be implemented separately.

In the illustrated embodiment, communication functions of the communication interface QQ212 may include cellular communication, Wi-Fi communication, LPWAN communication, data communication, voice communication, multimedia communication, short-range communications such as Bluetooth, near-field communication, location-based communication such as the use of the global positioning system (GPS) to determine a location, another like communication function, or any combination thereof. Communications may be implemented in according to one or more communication protocols and/or standards, such as IEEE 802.11, Code Division Multiplexing Access (CDMA), Wideband Code Division Multiple Access (WCDMA), GSM, LTE, New Radio (NR), UMTS, WiMax, Ethernet, transmission control protocol/internet protocol (TCP/IP), synchronous optical networking (SONET), Asynchronous Transfer Mode (ATM), QUIC, Hypertext Transfer Protocol (HTTP), and so forth.

FIG. 18 shows a network node QQ300 in accordance with some embodiments. As used herein, network node refers to equipment configured with a power feature aided ML model that models a behavior of a DPD and/or a non-linear device to reduce non-linear distortion of an output signal of a non-linear device. Examples of network nodes include, but are not limited to, access points (APs) (e.g., radio access points), base stations (BSs) (e.g., radio base stations, Node Bs, evolved Node Bs (cNBs) and NR NodeBs (gNBs)).

Base stations may be categorized based on the amount of coverage they provide (or, stated differently, their transmit power level) and so, depending on the provided amount of coverage, may be referred to as femto base stations, pico base stations, micro base stations, or macro base stations. A base station may be a relay node or a relay donor node controlling a relay. A network node may also include one or more (or all) parts of a distributed radio base station such as centralized digital units and/or remote radio units (RRUs), sometimes referred to as Remote Radio Heads (RRHs). Such remote radio units may or may not be integrated with an antenna as an antenna integrated radio. Parts of a distributed radio base station may also be referred to as nodes in a distributed antenna system (DAS).

Other examples of network nodes include multiple transmission point (multi-TRP) 5G access nodes, multi-standard radio (MSR) equipment such as MSR BSs, network controllers such as radio network controllers (RNCs) or base station controllers (BSCs), base transceiver stations (BTSs), transmission points, transmission nodes, multi-cell/multicast coordination entities (MCEs), Operation and Maintenance (O&M) nodes, Operations Support System (OSS) nodes, Self-Organizing Network (SON) nodes, positioning nodes (e.g., Evolved Serving Mobile Location Centers (E-SMLCs)), and/or Minimization of Drive Tests (MDTs).

The network node QQ300 includes a processing circuitry QQ302, a memory QQ304 that includes a power feature aided ML model, a communication interface QQ306. and a power source QQ308. The network node QQ300 may be composed of multiple physically separate components (e.g., a NodeB component and a RNC component, or a BTS component and a BSC component, etc.), which may each have their own respective components. In certain scenarios in which the network node QQ300 comprises multiple separate components (e.g., BTS and BSC components), one or more of the separate components may be shared among several network nodes. For example, a single RNC may control multiple NodeBs. In such a scenario, each unique NodeB and RNC pair, may in some instances be considered a single separate network node. In some embodiments, the network node QQ300 may be configured to support multiple radio access technologies (RATs). In such embodiments, some components may be duplicated (e.g., separate memory QQ304 for different RATs) and some components may be reused (e.g., a same antenna QQ310 may be shared by different RATs). The network node QQ300 may also include multiple sets of the various illustrated components for different wireless technologies integrated into network node QQ300, for example GSM, WCDMA, LTE, NR, WiFi, Zigbee, Z-wave, LoRaWAN, Radio Frequency Identification (RFID) or Bluetooth wireless technologies. These wireless technologies may be integrated into the same or different chip or set of chips and other components within network node QQ300.

The processing circuitry QQ302 may comprise a combination of one or more of a microprocessor, controller, microcontroller, central processing unit, digital signal processor, application-specific integrated circuit, field programmable gate array, or any other suitable computing device, resource, or combination of hardware, software and/or encoded logic operable to provide, either alone or in conjunction with other network node QQ300 components, such as the memory QQ304, to provide network node QQ300 functionality.

In some embodiments, the processing circuitry QQ302 includes a system on a chip (SOC) or an ASIC. In some embodiments, the processing circuitry QQ302 includes one or more of radio frequency (RF) transceiver circuitry QQ312 and baseband processing circuitry QQ314. In some embodiments, the radio frequency (RF) transceiver circuitry QQ312 and the baseband processing circuitry QQ314 may be on separate chips (or sets of chips), boards, or units, such as radio units and digital units. In alternative embodiments, part or all of RF transceiver circuitry QQ312 and baseband processing circuitry QQ314 may be on the same chip or set of chips, boards, or units.

The memory QQ304 may comprise any form of volatile or non-volatile computer-readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device-readable and/or computer-executable memory devices that store information, data, and/or instructions that may be used by the processing circuitry QQ302. The memory QQ304 may store any suitable instructions, data, or information, including a computer program, software, an application including one or more of logic, rules, code, tables, and/or other instructions capable of being executed by the processing circuitry QQ302 and utilized by the network node QQ300. The memory QQ304 may be used to store any calculations made by the processing circuitry QQ302 and/or any data received via the communication interface QQ306. In some embodiments, the processing circuitry QQ302 and memory QQ304 is integrated.

Embodiments of the network node QQ300 may include additional components beyond those shown in FIG. 18 for providing certain aspects of the network node's functionality, including any of the functionality described herein and/or any functionality necessary to support the subject matter described herein. For example, the network node QQ300 may include user interface equipment to allow input of information into the network node QQ300 and to allow output of information from the network node QQ300. This may allow a user to perform diagnostic, maintenance, repair, and other administrative functions for the network node QQ300.

FIG. 19 is a block diagram illustrating a virtualization environment QQ500 in which functions implemented by some embodiments may be virtualized to model a behavior of a DPD and/or a non-linear device to reduce non-linear distortion of an output signal of a non-linear device. In the present context, virtualizing means creating virtual versions of apparatuses or devices which may include virtualizing hardware platforms, storage devices and networking resources. As used herein, virtualization can be applied to any device described herein, or components thereof, and relates to an implementation in which at least a portion of the functionality is implemented as one or more virtual components. Some or all of the functions described herein may be implemented as virtual components executed by one or more virtual machines (VMs) implemented in one or more virtual environments QQ500 hosted by one or more of hardware nodes, such as a hardware computing device that operates as a network node, UE, core network node, or host. Further, in embodiments in which the virtual node does not require radio connectivity (e.g., a core network node or host), then the node may be entirely virtualized.

Applications QQ502 (which may alternatively be called software instances, virtual appliances, network functions, virtual nodes, virtual network functions, etc.) are run in the virtualization environment Q400 to implement some of the features, functions, and/or benefits of some of the embodiments disclosed herein.

Hardware QQ504 includes processing circuitry, memory that stores software and/or instructions executable by hardware processing circuitry, and/or other hardware devices as described herein, such as a network interface, input/output interface, and so forth. Software may be executed by the processing circuitry to instantiate one or more virtualization layers QQ506 (also referred to as hypervisors or virtual machine monitors (VMMs)), provide VMs QQ508a and QQ508b (one or more of which may be generally referred to as VMs QQ508), and/or perform any of the functions, features and/or benefits described in relation with some embodiments described herein. The virtualization layer QQ506 may present a virtual operating platform that appears like networking hardware to the VMs QQ508.

The VMs QQ508 comprise virtual processing, virtual memory, virtual networking or interface and virtual storage, and may be run by a corresponding virtualization layer QQ506. Different embodiments of the instance of a virtual appliance QQ502 may be implemented on one or more of VMs QQ508, and the implementations may be made in different ways. Virtualization of the hardware is in some contexts referred to as network function virtualization (NFV). NFV may be used to consolidate many network equipment types onto industry standard high volume server hardware, physical switches, and physical storage, which can be located in data centers, and customer premise equipment.

In the context of NFV. a VM QQ508 may be a software implementation of a physical machine that runs programs as if they were executing on a physical, non-virtualized machine. Each of the VMs QQ508, and that part of hardware QQ504 that executes that VM, be it hardware dedicated to that VM and/or hardware shared by that VM with others of the VMs, forms separate virtual network elements. Still in the context of NFV, a virtual network function is responsible for handling specific network functions that run in one or more VMs QQ508 on top of the hardware QQ504 and corresponds to the application QQ502.

Hardware QQ504 may be implemented in a standalone network node with generic or specific components. Hardware QQ504 may implement some functions via virtualization. Alternatively, hardware QQ504 may be part of a larger cluster of hardware (e.g. such as in a data center or CPE) where many hardware nodes work together and are managed via management and orchestration QQ510, which, among others, oversees lifecycle management of applications QQ502. In some embodiments, hardware QQ504 is coupled to one or more radio units that each include one or more transmitters and one or more receivers that may be coupled to one or more antennas. Radio units may communicate directly with other hardware nodes via one or more appropriate network interfaces and may be used in combination with the virtual components to provide a virtual node with radio capabilities, such as a radio access node or a base station. In some embodiments, some signaling can be provided with the use of a control system QQ512 which may alternatively be used for communication between hardware nodes and radio units.

Further definitions and embodiments are discussed below.

In the above-description of various embodiments of present inventive concepts, it is to be understood that the terminology used herein is for the purpose of describing particular embodiments only and is not intended to be limiting of present inventive concepts. Unless otherwise defined, all terms (including technical and scientific terms) used herein have the same meaning as commonly understood by one of ordinary skill in the art to which present inventive concepts belong. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

When an element is referred to as being “connected”, “coupled”, “responsive”. or variants thereof to another element, it can be directly connected, coupled, or responsive to the other element or intervening elements may be present. In contrast, when an element is referred to as being “directly connected”, “directly coupled”, “directly responsive”, or variants thereof to another element, there are no intervening elements present. Like numbers refer to like elements throughout. Furthermore, “coupled”, “connected”, “responsive”, or variants thereof as used herein may include wirelessly coupled, connected, or responsive. As used herein, the singular forms “a”, “an” and “the” are intended to include the plural forms as well, unless the context clearly indicates otherwise. Well-known functions or constructions may not be described in detail for brevity and/or clarity. The term “and/or” (abbreviated “/”) includes any and all combinations of one or more of the associated listed items.

It will be understood that although the terms first, second, third, etc. may be used herein to describe various elements/operations, these elements/operations should not be limited by these terms. These terms are only used to distinguish one element/operation from another element/operation. Thus a first element/operation in some embodiments could be termed a second element/operation in other embodiments without departing from the teachings of present inventive concepts. The same reference numerals or the same reference designators denote the same or similar elements throughout the specification.

As used herein, the terms “comprise”, “comprising”, “comprises”, “include”, “including”, “includes”, “have”, “has”, “having”, or variants thereof are open-ended, and include one or more stated features, integers, elements, steps, components or functions but does not preclude the presence or addition of one or more other features, integers, elements, steps, components, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

Example embodiments are described herein with reference to block diagrams and/or flowchart illustrations of computer-implemented methods, apparatus (systems and/or devices) and/or computer program products. It is understood that a block of the block diagrams and/or flowchart illustrations, and combinations of blocks in the block diagrams and/or flowchart illustrations, can be implemented by computer program instructions that are performed by one or more computer circuits. These computer program instructions may be provided to a processor circuit of a general purpose computer circuit, special purpose computer circuit, and/or other programmable data processing circuit to produce a machine, such that the instructions, which execute via the processor of the computer and/or other programmable data processing apparatus, transform and control transistors, values stored in memory locations, and other hardware components within such circuitry to implement the functions/acts specified in the block diagrams and/or flowchart block or blocks, and thereby create means (functionality) and/or structure for implementing the functions/acts specified in the block diagrams and/or flowchart block(s).

These computer program instructions may also be stored in a tangible computer-readable medium that can direct a computer or other programmable data processing apparatus to function in a particular manner, such that the instructions stored in the computer-readable medium produce an article of manufacture including instructions which implement the functions/acts specified in the block diagrams and/or flowchart block or blocks. Accordingly, embodiments of present inventive concepts may be embodied in hardware and/or in software (including firmware, resident software, micro-code, etc.) that runs on a processor such as a digital signal processor, which may collectively be referred to as “circuitry,” “a module” or variants thereof.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of inventive concepts. Moreover, although some of the diagrams include arrows on communication paths to show a primary direction of communication, it is to be understood that communication may occur in the opposite direction to the depicted arrows.

Many variations and modifications can be made to the embodiments without substantially departing from the principles of the present inventive concepts. All such variations and modifications are intended to be included herein within the scope of present inventive concepts. Accordingly, the above disclosed subject matter is to be considered illustrative, and not restrictive, and the examples of embodiments are intended to cover all such modifications, enhancements, and other embodiments, which fall within the spirit and scope of present inventive concepts. Thus, to the maximum extent allowed by law, the scope of present inventive concepts is to be determined by the broadest permissible interpretation of the present disclosure including the examples of embodiments and their equivalents, and shall not be restricted or limited by the foregoing detailed description.

1. A computer-implemented method performed by a device configured with a power feature aided machine learning, ML, model that models a behavior of a digital predistortion, DPD, to reduce non-linear distortion of an output signal of a non-linear device, the method comprising:
extracting, for a point in time in a time period, a plurality of power features from an input signal destined to be input to the DPD;
labelling the extracted plurality of power features to obtain at least one labelled average power level;
inputting the at least one labelled average power level to the input of the ML model to obtain an output signal from the ML model having characteristics to reduce the non-linear distortion of the output signal of the non-linear device; and
providing the output signal from the ML model as an input to the non-linear device.

2. The method according to claim 1, wherein the input signal destined to be input to the DPD further comprises a historical input signal from a filter in the power feature extraction.

3. The method according to claim 1, wherein the extracting is repeated for additional points in time in the time period.

4. The method according to claim 1, wherein the power feature extraction comprises a plurality of different memory lengths, wherein the labelling comprises applying at least one filter to the extracted plurality of power features to obtain an average power, and wherein the filter adjusts for differences in the extracted plurality of power features and differences in the plurality of different memory lengths for power feature extraction.

5. The method according to claim 4, wherein the at least one filter comprises at least one of a moving-average filter, an exponential moving-average filter, and autoregressive filter, and autoregressive moving-average filter, and a symbol-based filter.

6. The method according to claim 1, wherein the at least one labelled average power level comprises a filtered average power level that is labelled as one power level.

7. The method according to claim 1, wherein the time period comprises a plurality of different time periods having different durations.

8. The method according to claim 1, wherein the time period comprises a plurality of different time periods having different durations, and wherein the extracting is repeated and identifies a power feature from the input signal destined to be input to the DPD over at least one different time period having a different duration.

9. The method according to claim 1, wherein the ML model comprises a tree-based power feature aided gradient boosting, GB, model and/or a power feature aided extreme gradient boosting, XGB, model.

10. The method according to claim 9, further comprising:
training the power feature aided GB model and/or the power feature aided XGB model to learn behavior of the digital predistortion, DPD, for the non-linear device.

11. The method according to claim 10, wherein input signal destined to be input to the DPD comprises a first input signal to the ML model, and wherein the training (501) comprises:
comparing the output signal from the ML model with a target output signal and identifying an error based on the comparison;
based on identifying the error, updating the first input signal to compute a new input signal destined to be input to the DPD for a next iteration; and
iteratively repeating the extracting, the labelling, the inputting, the providing, the comparing, and the updating until the target output signal is approached.

12. The method according to claim 10, wherein the training is performed offline in a communications system.

13. The method according to claim 9, further comprising:
applying the power feature aided GB model and/or the power feature aided XGB model online to perform the providing; and
periodically updating the power feature aided GB model and/or the power feature aided XGB model with the power feature aided GB model based training and/or the power feature aided XGB model based training to learn behavior of the DPD for the non-linear device.

14. (canceled)

15. The method according to claim 1, wherein the method further comprises modeling a behavior of the non-linear device.

16. The method according to claim 1, wherein the non-linear device comprises a power amplifier.

17. The method according to claim 1, wherein the non-linear device comprises a component in a radio unit of a base station or a component in a user equipment.

18. A device configured with a power feature aided machine learning, ML model that models a behavior of digital predistortion, DPD, to reduce non-linear distortion of an output signal of a non-linear device, the device comprising:
at least one processor;
at least one memory connected to the at least one processor and storing program code that is executed by the at least one processor to perform operations comprising:
extract, for a point in time in a time period, a plurality of power features from an input signal destined to be an input to the DPD;
label the extracted plurality of power features to obtain at least one labelled average power level;
input the at least one labelled average power level to the input of the ML model to obtain an output signal from the ML model having characteristics to reduce the non-linear distortion of the output signal of the non-linear device; and
provide the output signal from the ML model as an input to the non-linear device.

19. The device according to claim 18, wherein the power feature extraction comprises a plurality of different memory lengths, wherein the labelling comprises applying at least one filter to the extracted plurality of power features to obtain an average power, and wherein the filter adjusts for differences in the extracted plurality of power features and differences in the plurality of different memory lengths for power feature extraction.

20-23. (canceled)

24. A computer program product comprising a non-transitory storage medium including program code to be executed by processing circuitry of a device configured with a power feature aided machine learning, ML model that models a behavior of a digital predistortion, DPD, to reduce non-linear distortion of an output signal of a non-linear device, whereby execution of the program code causes the device to perform operations comprising:
extract, for a point in time in a time period, a plurality of power features from an input signal destined to be an input to the DPD;
label the extracted plurality of power features to obtain at least one labelled average power level;
input the at least one labelled average power level to the input of the ML model to obtain an output signal from the ML model having characteristics to reduce the non-linear distortion of the output signal of the non-linear device; and
provide output signal from the ML model as an input to the non-linear device.

25. The computer program product according to claim 24, wherein the power feature extraction comprises a plurality of different memory lengths, wherein the labelling comprises applying at least one filter to the extracted plurality of power features to obtain an average power, and wherein the filter adjusts for differences in the extracted plurality of power features and differences in the plurality of different memory lengths for power feature extraction.
